(19) United States
(12) Patent Application Publication
(10) Pub. No.: US 2023/0320142 A1
(43) Pub. Date: Oct. 5, 2023

(54) DISPLAY DEVICE AND MANUFACTURING METHOD OF DISPLAY DEVICE

(71) Applicant: Japan Display Inc., Tokyo (JP)

(72) Inventors: Hirofumi MIZUKOSHI, Tokyo (JP); Kaichi FUKUDA, Tokyo (JP); Takanobu TAKENAKA, Tokyo (JP); Masaru TAKAYAMA, Tokyo (JP)

(73) Assignee: Japan Display Inc., Tokyo (JP)

(21) Appl. No.: 18/190,158

(22) Filed: Mar. 27, 2023

(30) Foreign Application Priority Data
Mar. 30, 2022 (JP) 2022-056358

(51) Int. Cl. H10K 59/122; H10K 59/12; H10K 59/35

(52) U.S. Cl. CPC H10K 59/122; H10K 59/1201; H10K 59/35

(57) ABSTRACT

According to one embodiment, in a manufacturing method of a display device, a first etching stopper layer and a first sealing layer is formed. A second etching stopper layer and a second sealing layer is formed. A third etching stopper layer and a third sealing layer is formed. An etching rate of the first etching stopper layer is less than an etching rate of the first sealing layer. An etching rate of the second etching stopper layer is less than an etching rate of the second sealing layer. An etching rate of the third etching stopper layer is less than an etching rate of the third sealing layer. A thickness of each of the first etching stopper layer and the second etching stopper layer is greater than a thickness of the third etching stopper layer.

### CROSS-REFERENCE TO RELATED APPLICATIONS

This application is based upon and claims the benefit of priority from Japanese Patent Application No. 2022-056358, filed Mar. 30, 2022, the entire contents of which are incorporated herein by reference.

### FIELD

Embodiments described herein relate generally to a display device and a manufacturing method of the display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole-transport layer and an electron-transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram showing an example of the configuration of display elements 201 to 203.

FIG. 5 is a diagram showing an example of the simulation results of the relationships between the thicknesses of the etching stopper layers shown in FIG. 4 and the luminous efficiency.

FIG. 6 is a diagram showing another example of the configuration of the display elements 201 to 203.

FIG. 7 is a diagram showing an example of the simulation results of the relationships between the thicknesses of the etching stopper layers shown in FIG. 6 and the luminous efficiency.

FIG. 8 is a flow diagram for explaining an example of the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the process of removing a first thin film 31 in the subpixel SP2.

FIG. 13 is a diagram for explaining the manufacturing method of the display device DSP.

FIG. 14 is a diagram for explaining the manufacturing method of the display device DSP.

FIG. 15 is a diagram for explaining the manufacturing method of the display device DSP.

FIG. 16 is a diagram for explaining the manufacturing method of the display device DSP.

FIG. 17 is a diagram for explaining the manufacturing method of the display device DSP.

FIG. 18 is a diagram for explaining the manufacturing method of the display device DSP.

### DETAILED DESCRIPTION

Embodiments described herein aim to provide a display device which can prevent the reduction in reliability and a manufacturing method of such a display device.

In general, according to one embodiment, a manufacturing method of a display device comprises preparing a processing substrate by forming a first lower electrode of a first subpixel, a second lower electrode of a second subpixel and a third lower electrode of a third subpixel and by forming a rib comprising a first aperture overlapping the first lower electrode, a second aperture overlapping the second lower electrode and a third aperture overlapping the third lower electrode, forming a first thin film including a first organic layer including a first light emitting layer over the first subpixel, the second subpixel and the third subpixel, a first etching stopper layer on the rib and the first organic layer, and a first sealing layer on the first etching stopper layer, removing the first thin film in the second subpixel and the third subpixel such that the first thin film remains in the first subpixel, forming a second thin film including a second organic layer including a second light emitting layer over the first subpixel comprising the first thin film, the second subpixel and the third subpixel, a second etching stopper layer on the rib and the second organic layer, and a second sealing layer on the second etching stopper layer, removing the second thin film in the first subpixel and the third subpixel such that the second thin film remains in the second subpixel, forming a third thin film including a third organic layer including a third light emitting layer over the first subpixel comprising the first thin film, the second subpixel comprising the second thin film and the third subpixel, a third etching stopper layer on the rib and the third organic layer, and a third sealing layer on the third etching stopper layer, and removing the third thin film in the first subpixel and the second subpixel such that the third thin film remains in the third subpixel. An etching rate of the first etching stopper layer is less than an etching rate of the first sealing layer. An etching rate of the second etching stopper layer is less than an etching rate of the second sealing layer. An etching rate of the third etching stopper layer is less than an etching rate of the third sealing layer. A thickness of each of the first etching stopper layer and the second etching stopper layer is greater than a thickness of the third etching stopper layer.

According to another embodiment, a display device comprises a substrate, a first lower electrode, a second lower electrode and a third lower electrode provided above the substrate, a rib comprising a first aperture overlapping the first lower electrode, a second aperture overlapping the second lower electrode and a third aperture overlapping the third lower electrode, a partition comprising a lower portion provided on the rib and an upper portion provided on the lower portion and protruding from a side surface of the lower portion, a first organic layer provided on the first lower electrode in the first aperture and including a first light emitting layer, a first etching stopper layer which is provided on the rib and the first organic layer and is in contact with the partition, a first sealing layer which is provided on the first etching stopper layer and is in contact with the partition, a second organic layer provided on the second lower electrode in the second aperture and including a second light emitting layer, a second etching stopper layer which is provided on the rib and the second organic layer and is in contact with the partition, a second sealing layer which is provided on the second etching stopper layer and is in contact with the partition, a third organic layer provided on the third lower electrode in the third aperture and including a third light emitting layer, a third etching stopper layer which is provided on the rib and the third organic layer and is in contact with the partition, and a third sealing layer which is provided on the third etching stopper layer and is in contact with the partition. A thickness of each of the first etching stopper layer and the second etching stopper layer is greater than a thickness of the third etching stopper layer.

The embodiments can provide a display device which can prevent the reduction in reliability and a manufacturing method of such a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction. A direction parallel to the Y-axis is referred to as a second direction. A direction parallel to the Z-axis is referred to as a third direction. A plan view is defined as appearance when various types of elements are viewed parallel to the third direction Z.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

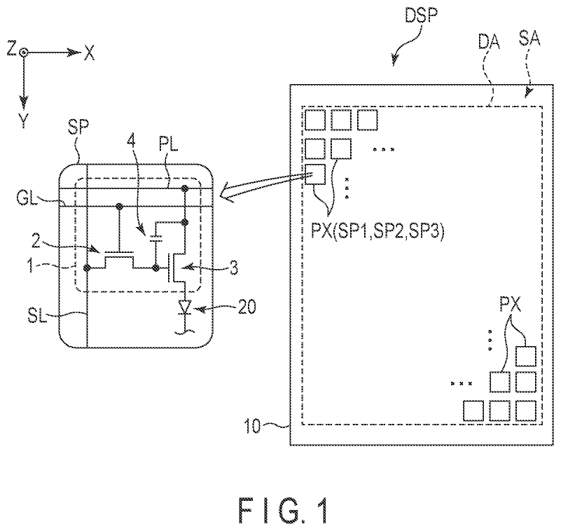

FIG. 1 is a diagram showing a configuration example of a display device DSP.

The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in a plan view. It should be noted that the shape of the substrate 10 in the plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a subpixel SP1 which exhibits a first color, a subpixel SP2 which exhibits a second color and a subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and the drain electrode of the pixel switch 2 is connected to a signal line SL, and the other one is connected to the gate electrode of the drive transistor 3 and the capacitor 4. In the drive transistor 3, one of the source electrode and the drain electrode is connected to a power line PL and the capacitor 4, and the other one is connected to an anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

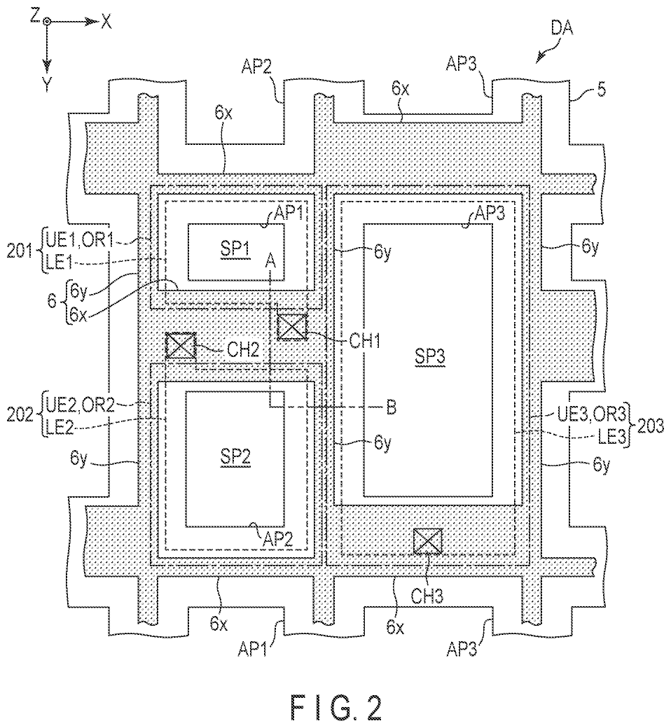

FIG. 2 is a diagram showing an example of the layout of subpixels SP1, SP2 and SP3.

In the example of FIG. 2, subpixels SP1 and SP2 are arranged in the second direction Y. Further, each of subpixels SP1 and SP2 is adjacent to the subpixel SP3 in the first direction X.

When subpixels SP1, SP2 and SP3 are provided in line with this layout, in the display area DA, a column in which subpixels SP1 and SP2 are alternately provided in the second direction Y and a column in which a plurality of subpixels SP3 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 as seen in the plan view. The partition 6 comprises a plurality of first partitions 6x extending in the first direction X and a plurality of second partitions 6y extending in the second direction Y. The first partitions 6x are provided between the apertures AP1 and AP2 which are adjacent to each other in the second direction Y and between two apertures AP3 which are adjacent to each other in the second direction Y. Each second partition 6y is provided between the apertures AP1 and AP3 which are adjacent to each other in the first direction X and between the apertures AP2 and AP3 which are adjacent to each other in the first direction X.

In the example of FIG. 2, the first partitions 6x and the second partitions 6y are connected to each other. Thus, the partition 6 is formed into a grating shape surrounding the apertures AP1, AP2 and AP3 as a whole. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

The subpixel SP1 comprises a lower electrode LE1, an upper electrode UE1 and an organic layer OR1 overlapping the aperture AP1. The subpixel SP2 comprises a lower electrode LE2, an upper electrode UE2 and an organic layer OR2 overlapping the aperture AP2. The subpixel SP3 comprises a lower electrode LE3, an upper electrode UE3 and an organic layer OR3 overlapping the aperture AP3.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. The peripheral portion of each of the lower electrodes LE1, LE2 and LE3 overlaps the rib 5. The outer shape of the upper electrode UE1 is substantially coincident with the outer shape of the organic layer OR1. The peripheral portion of each of the upper electrode UE1 and the organic layer OR1 overlaps the partition 6. The outer shape of the upper electrode UE2 is substantially coincident with the outer shape of the organic layer OR2. The peripheral portion of each of the upper electrode UE2 and the organic layer OR2 overlaps the partition 6. The outer shape of the upper electrode UE3 is substantially coincident with the outer shape of the organic layer OR3. The peripheral portion of each of the upper electrode UE3 and the organic layer OR3 overlaps the partition 6.

The lower electrode LE1, the upper electrode UE1 and the organic layer OR1 constitute the display element 201 of the subpixel SP1. The lower electrode LE2, the upper electrode UE2 and the organic layer OR2 constitute the display element 202 of the subpixel SP2. The lower electrode LE3, the upper electrode UE3 and the organic layer OR3 constitute the display element 203 of the subpixel SP3.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of the subpixel SP1 through a contact hole CH1. The lower electrode LE2 is connected to the pixel circuit 1 of the subpixel SP2 through a contact hole CH2. The lower electrode LE3 is connected to the pixel circuit 1 of the subpixel SP3 through a contact hole CH3.

In the example of FIG. 2, the area of the aperture AP3 is greater than that of the aperture AP2, and the area of the aperture AP2 is greater than that of the aperture AP1. In other words, the area of the lower electrode LE3 exposed from the aperture AP3 is greater than that of the lower electrode LE2 exposed from the aperture AP2. The area of the lower electrode LE2 exposed from the aperture AP2 is greater than that of the lower electrode LE1 exposed from the aperture AP1.

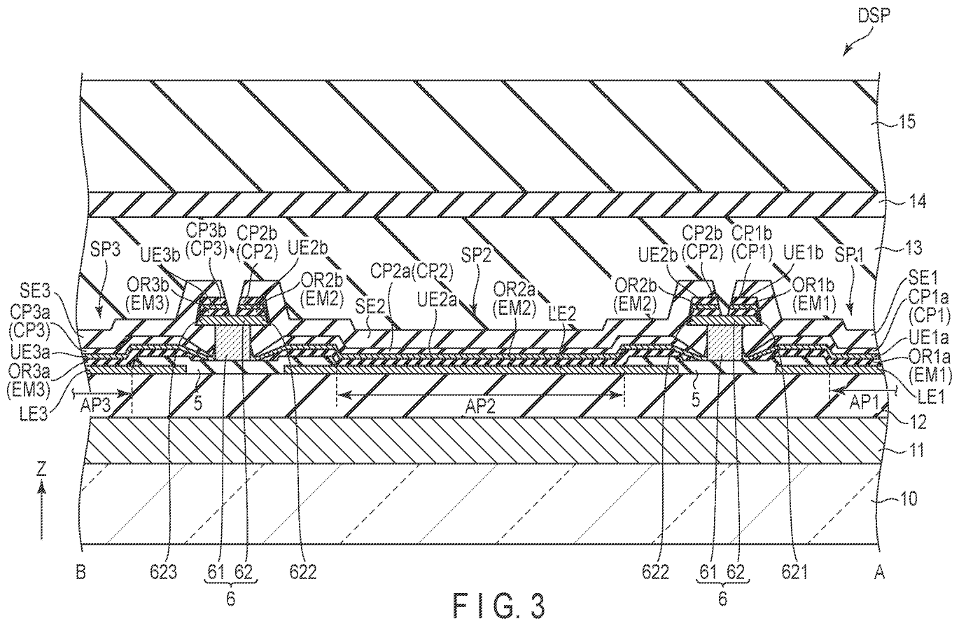

FIG. 3 is a schematic cross-sectional view of the display device DSP along the A-B line of FIG. 2.

A circuit layer 11 is provided on the substrate 10 described above. The circuit layer 11 includes various circuits such as the pixel circuit 1, and various lines such as the scanning line GL, the signal line SL and the power line PL shown in FIG. 1. The circuit layer 11 is covered with an insulating layer 12. The insulating layer 12 functions as a planarization film which planarizes the irregularities formed by the circuit layer 11.

The lower electrodes LE1, LE2 and LE3 are provided on the insulating layer 12. The rib 5 is provided on the insulating layer 12 and the lower electrodes LE1, LE2 and LE3. The end portions of the lower electrodes LE1, LE2 and LE3 are covered with the rib 5. In other words, the end portions of the lower electrodes LE1, LE2 and LE3 are provided between the insulating layer 12 and the rib 5. Of the lower electrodes LE1, LE2 and LE3, between the lower electrodes which are adjacent to each other, the insulating layer 12 is covered with the rib 5.

The partition 6 includes a lower portion (stem) 61 provided on the rib 5 and an upper portion (shade) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. By this configuration, in FIG. 3, the both end portions of the upper portion 62 protrude relative to the side surfaces of the lower portion 61. This shape of the partition 6 may be called an overhang shape. Of the upper portion 62, a portion which protrudes relative to the lower portion 61 may be simply called a protrusion.

The organic layer OR1 shown in FIG. 2 includes first and second portions OR1a and OR1b spaced apart from each other as shown in FIG. 3. The first portion OR1a is in contact with the lower electrode LE1 through the aperture AP1, covers the lower electrode LE1 and overlaps part of the rib 5. The second portion OR1b is provided on the upper portion 62.

The upper electrode UE1 shown in FIG. 2 includes first and second portions UE1a and UE1b spaced apart from each other as shown in FIG. 3. The first portion UE1a faces the lower electrode LE1 and is provided on the first portion OR1a. Further, the first portion UE1a is in contact with the side surface of the lower portion 61. The second portion UE1b is located above the partition 6 and is provided on the second portion OR1b.

The first portion OR1a and the first portion UE1a are located on the lower side relative to the upper portion 62.

The organic layer OR2 shown in FIG. 2 includes first and second portions OR2a and OR2b spaced apart from each other as shown in FIG. 3. The first portion OR2a is in contact with the lower electrode LE2 through the aperture AP2, covers the lower electrode LE2 and overlaps part of the rib 5. The second portion OR2b is provided on the upper portion 62.

The upper electrode UE2 shown in FIG. 2 includes first and second portions UE2a and UE2b spaced apart from each other as shown in FIG. 3. The first portion UE2a faces the lower electrode LE2 and is provided on the first portion OR2a. Further, the first portion UE2a is in contact with the side surface of the lower portion 61. The second portion UE2b is located above the partition 6 and is provided on the second portion OR2b.

The first portion OR2a and the first portion UE2a are located on the lower side relative to the upper portion 62.

The organic layer OR3 shown in FIG. 2 includes first and second portions OR3a and OR3b spaced apart from each other as shown in FIG. 3. The first portion OR3a is in contact with the lower electrode LE3 through the aperture AP3, covers the lower electrode LE3 and overlaps part of the rib 5. The second portion OR3b is provided on the upper portion 62.

The upper electrode UE3 shown in FIG. 2 includes first and second portions UE3a and UE3b spaced apart from each other as shown in FIG. 3. The first portion UE3a faces the lower electrode LE3 and is provided on the first portion OR3a. Further, the first portion UE3a is in contact with the side surface of the lower portion 61. The second portion UE3b is located above the partition 6 and is provided on the second portion OR3b.

The first portion OR3a and the first portion UE3a are located on the lower side relative to the upper portion 62.

In the example shown in FIG. 3, subpixels SP1, SP2 and SP3 include cap layers (optical adjustment layers) CP1, CP2 and CP3 for adjusting the optical property of light emitted from light emitting layers of the organic layers OR1, OR2 and OR3.

The cap layer CP1 includes first and second portions CP1a and CP1b spaced apart from each other. The first portion CP1a is located in the aperture AP1, is located on the lower side relative to the upper portion 62 and is provided on the first portion UE1a. The second portion CP1b is located above the partition 6 and is provided on the second portion UE1b.

The cap layer CP2 includes first and second portions CP2a and CP2b spaced apart from each other. The first portion CP2a is located in the aperture AP2, is located on the lower side relative to the upper portion 62 and is provided on the first portion UE2a. The second portion CP2b is located above the partition 6 and is provided on the second portion UE2b.

The cap layer CP3 includes first and second portions CP3a and CP3b spaced apart from each other. The first portion CP3a is located in the aperture AP3, is located on the lower side relative to the upper portion 62 and is provided on the first portion UE3a. The second portion CP3b is located above the partition 6 and is provided on the second portion UE3b.

Sealing layers SE1, SE2 and SE3 are provided in subpixels SP1, SP2 and SP3, respectively.

The sealing layer SE1 is in contact with the first portion CP1a, the lower and upper portions 61 and 62 of the partition 6 and the second portion CP1b and continuously covers the members of the subpixel SP1. It should be noted that the sealing layer SE1 may comprise a void under the upper portion 62 of the partition 6 (under a protrusion 621). However, the illustration thereof is omitted here.

The sealing layer SE2 is in contact with the first portion CP2a, the lower and upper portions 61 and 62 of the partition 6 and the second portion CP2b and continuously covers the members of the subpixel SP2. It should be noted that the sealing layer SE2 may comprise a void under the upper portion 62 of the partition 6 (under a protrusion 622). However, the illustration thereof is omitted here.

The sealing layer SE3 is in contact with the first portion CP3a, the lower and upper portions 61 and 62 of the partition 6 and the second portion CP3b and continuously covers the members of the subpixel SP3. It should be noted that the sealing layer SE3 may comprise a void under the upper portion 62 of the partition 6 (under a protrusion 623). However, the illustration thereof is omitted here.

The sealing layers SE1, SE2 and SE3 are covered with a protective layer 13.

In the example of FIG. 3, on the partition 6 between subpixels SP1 and SP2, the second portion OR1b of the organic layer OR1 is spaced apart from the second portion OR2b of the organic layer OR2, and the second portion UE1b of the upper electrode UE1 is spaced apart from the second portion UE2b of the upper electrode UE2, and the second portion CP1b of the cap layer CP1 is spaced apart from the second portion CP2b of the cap layer CP2, and the sealing layer SE1 is spaced apart from the sealing layer SE2. The protective layer 13 is provided between the second portion OR1b and the second portion OR2b, between the second portion UE1b and the second portion UE2b, between the second portion CP1b and the second portion CP2b and between the sealing layer SE1 and the sealing layer SE2.

On the partition 6 between subpixels SP2 and SP3, the second portion OR2b of the organic layer OR2 is spaced apart from the second portion OR3b of the organic layer OR3, and the second portion UE2b of the upper electrode UE2 is spaced apart from the second portion UE3b of the upper electrode UE3, and the second portion CP2b of the cap layer CP2 is spaced apart from the second portion CP3b of the cap layer CP3, and the sealing layer SE2 is spaced apart from the sealing layer SE3. The protective layer 13 is provided between the second portion OR2b and the second portion OR3b, between the second portion UE2b and the second portion UE3b, between the second portion CP2b and the second portion CP3b and between the sealing layer SE2 and the sealing layer SE3.

The insulating layer 12 is an organic insulating layer. The rib 5 and the sealing layers SE1, SE2 and SE3 are inorganic insulating layers.

The sealing layers SE1, SE2 and SE3 are formed of, for example, the same inorganic insulating material.

The rib 5 is formed of silicon nitride (SiNx) as an example of inorganic insulating materials. It should be noted that the rib 5 may be formed as, as another inorganic insulating material, a single-layer body of one of silicon oxide (SiOx), silicon oxynitride (SiON) and aluminum oxide (Al₂O₃). The rib 5 may be formed as a stacked layer body of a combination consisting of at least two of a silicon nitride layer, a silicon oxide layer, a silicon oxynitride layer and an aluminum oxide layer.

The sealing layers SE1, SE2 and SE3 are formed of silicon nitride (SiNx) as an example of inorganic insulating materials. It should be noted that the sealing layers SE1, SE2 and SE3 may be formed as, as another inorganic insulating material, a single-layer body of one of silicon oxide (SiOx), silicon oxynitride (SiON) and aluminum oxide (Al₂O₃). The sealing layers SE1, SE2 and SE3 may be formed as a stacked layer body of a combination consisting of at least two of a silicon nitride layer, a silicon oxide layer, a silicon oxynitride layer and an aluminum oxide layer. Thus, the sealing layers SE1, SE2 and SE3 may be formed of the same material as the rib 5.

The lower portion 61 of the partition 6 is formed of a conductive material and is electrically connected to the first portions UE1a, UE2a and UE3a of the upper electrodes. Both the lower portion 61 and the upper portion 62 of the partition 6 may be conductive.

The thickness of the rib 5 is sufficiently less than the thickness of each of the partition 6 and the insulating layer 12. For example, the thickness of the rib 5 is greater than or equal to 200 nm but less than or equal to 400 nm.

The thickness of the sealing layer SE1, the thickness of the sealing layer SE2 and the thickness of the sealing layer SE3 are substantially equal to each other.

The thickness of the lower portion 61 of the partition 6 (the thickness from the upper surface of the rib 5 to the lower surface of the upper portion 62) is greater than that of the rib 5.

The lower electrodes LE1, LE2 and LE3 may be formed of a transparent conductive material such as ITO or may comprise a multilayer structure of a metal material such as silver (Ag) and a transparent conductive material. The upper electrodes UE1, UE2 and UE3 are formed of, for example, a metal material such as an alloy of magnesium and silver (MgAg). The upper electrodes UE1, UE2 and UE3 may be formed of a transparent conductive material such as ITO.

When the potential of the lower electrodes LE1, LE2 and LE3 is relatively higher than that of the upper electrodes UE1, UE2 and UE3, the lower electrodes LE1, LE2 and LE3 correspond to anodes, and the upper electrodes UE1, UE2 and UE3 correspond to cathodes. When the potential of the upper electrodes UE1, UE2 and UE3 is relatively higher than that of the lower electrodes LE1, LE2 and LE3, the upper electrodes UE1, UE2 and UE3 correspond to anodes, and the lower electrodes LE1, LE2 and LE3 correspond to cathodes.

Each of the organic layers OR1, OR2 and OR3 includes a plurality of functional layers. The first and second portions OR1a and OR1b of the organic layer OR1 include light emitting layers EM1 formed of the same material. The first and second portions OR2a and OR2b of the organic layer OR2 include light emitting layers EM2 formed of the same material. The light emitting layers EM2 are formed of a material different from that of the light emitting layers EM1. The first and second portions OR3a and OR3b of the organic layer OR3 include light emitting layers EM3 formed of the same material. The light emitting layers EM3 are formed of a material different from the materials of the light emitting layers EM1 and EM2.

The material of the light emitting layers EM1, the material of the light emitting layers EM2 and the material of the light emitting layers EM3 are materials which emit light in different wavelength ranges.

In other words, the light emitting layer EM1 is formed of a material which emits light in a first wavelength range. The light emitting layer EM2 is formed of a material which emits light in a second wavelength range different from the first wavelength range. The light emitting layer EM3 is formed of a material which emits light in a third wavelength range different from the first wavelength range and the second wavelength range.

The cap layers CP1, CP2 and CP3 are formed by, for example, a multilayer body of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that the cap layers CP1, CP2 and CP3 may be omitted.

The protective layer 13 is a transparent organic insulating layer. A sealing layer 14 is a transparent inorganic insulating layer and is provided on the protective layer 13. The sealing layer 14 is formed of, for example, silicon nitride (SiNx). An overcoat layer 15 is a transparent organic insulating layer and is provided on the sealing layer 14.

Common voltage is applied to the partition 6. This common voltage is applied to, of the upper electrodes, the first portions UE1a, UE2a and UE3a which are in contact with the side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the lower electrode LE1 and the upper electrode UE1, the light emitting layer EM1 of the first portion OR1a of the organic layer OR1 emits light in the first wavelength range. When a potential difference is formed between the lower electrode LE2 and the upper electrode UE2, the light emitting layer EM2 of the first portion OR2a of the organic layer OR2 emits light in the second wavelength range. When a potential difference is formed between the lower electrode LE3 and the upper electrode UE3, the light emitting layer EM3 of the first portion OR3a of the organic layer OR3 emits light in the third wavelength range.

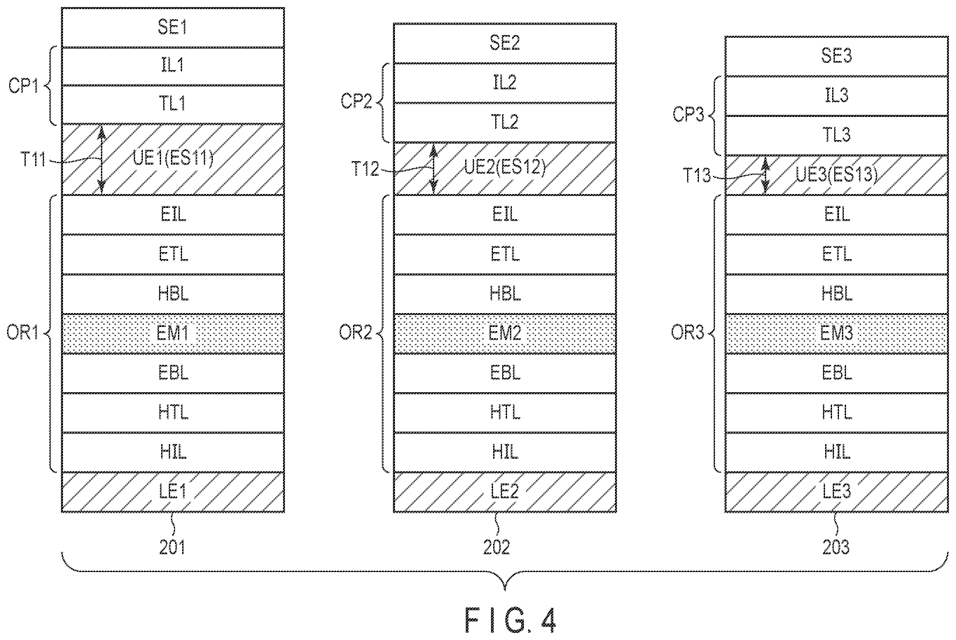

FIG. 4 is a diagram showing an example of the configuration of the display elements 201 to 203. Here, in the example, this specification assumes that each lower electrode corresponds to the anode and each upper electrode corresponds to the cathode.

The display element 201 includes the organic layer OR1 between the lower electrode LE1 and the upper electrode UE1.

In the organic layer OR1, a hole-injection layer HIL, a hole-transport layer HTL and an electron blocking layer EBL are located between the lower electrode LE1 and the light emitting layer EM1. The hole-injection layer HIL is provided on the lower electrode LE1. The hole-transport layer HTL is provided on the hole-injection layer HIL. The electron blocking layer EBL is provided on the hole-transport layer HTL. The light emitting layer EM1 is provided on the electron blocking layer EBL.

In the organic layer OR1, a hole blocking layer HBL, an electron-transport layer ETL and an electron-injection layer EIL are located between the light emitting layer EM1 and the upper electrode UE1. The hole blocking layer HBL is provided on the light emitting layer EM1. The electron-transport layer ETL is provided on the hole blocking layer HBL. The electron-injection layer EIL is provided on the electron-transport layer ETL. The upper electrode UE1 is provided on the electron-injection layer EIL.

It should be noted that the organic layer OR1 may include, in addition to the functional layers described above, other functional layers such as a carrier generation layer as needed, or at least one of the above functional layers may be omitted.

The cap layer CP1 includes a transparent layer TL1 and an inorganic layer IL1. The transparent layer TL1 is provided on the upper electrode UE1. The inorganic layer IL1 is provided on the transparent layer TL1. The sealing layer SE1 is provided on the inorganic layer IL1.

The transparent layer TL1 is, for example, an organic layer formed of an organic material, and is a high refractive layer having a refractive index greater than that of the upper electrode UE1. The inorganic layer IL1 is a transparent thin film formed of, for example, lithium fluoride (LiF) or silicon oxide (SiO) and is a low refractive layer having a refractive index less than that of the transparent layer TL1.

In the example shown in FIG. 4, the cap layer CP1 is a stacked layer body consisting of the two layers of the transparent layer TL1 and the inorganic layer IL1. However, the cap layer CP1 may be a stacked layer body consisting of three or more layers. In the cap layer CP1, the inorganic layer IL1 is located as the top layer and is covered with the sealing layer SE1.

The display element 202 is configured in the same manner as the display element 201 excluding the structure in which the organic layer OR2 between the lower electrode LE2 and the upper electrode UE2 includes the light emitting layer EM2 instead of the light emitting layer EM1.

The transparent layer TL2 of the cap layer CP2 is provided on the upper electrode UE2. The inorganic layer IL2 of the cap layer CP2 is covered with the sealing layer SE2.

The display element 203 is configured in the same manner as the display element 201 excluding the structure in which the organic layer OR3 between the lower electrode LE3 and the upper electrode UE3 includes the light emitting layer EM3 instead of the light emitting layer EM1.

The transparent layer TL3 of the cap layer CP3 is provided on the upper electrode UE3. The inorganic layer IL3 of the cap layer CP3 is covered with the sealing layer SE3.

The functional layers shown in FIG. 4 such as the hole-injection layer HIL, the hole-transport layer HTL, the electron blocking layer EBL, the hole blocking layer HBL, the electron-transport layer ETL and the electron-injection layer EIL are provided for all of the display elements 201 to 203. However, the functional layers are divided for each of the display elements 201 to 203 and are individually formed for each of the display elements 201 to 203. The thickness of each of the above functional layers may differ depending on the display element.

When this specification focuses attention on one of the functional layers described above, the functional layer of one of the display elements 201 to 203 may be formed of a material different from that of the functional layers of the other two display elements, or all of the functional layers of the display elements 201 to 203 may be formed of materials different from each other.

Further, the layer structure of one of the display elements 201 to 203 may be different from that of the other two display elements, or all of the layer structures of the display elements 201 to 203 may be different from each other. For example, when this specification focuses attention on one of the functional layers, one of the display elements 201 to 203 may not include this functional layer, or only one of the display elements 201 to 203 may include the functional layer. When this specification focuses attention on one of the functional layers, for example, this functional layer may comprise a multilayer structure in one of the display elements 201 to 203.

The transparent layers TL1 to TL3 are spaced apart from each other and are individually formed. Thus, all of the transparent layers TL1 to TL3 may be formed of the same material, or one of the transparent layers TL1 to TL3 may be formed of a material different from that of the other two transparent layers, or all of the transparent layers TL1 to TL3 may be formed of materials different from each other. All of the thicknesses of the transparent layers TL1 to TL3 may be the same as each other, or may be different from each other.

The inorganic layers IL1 to IL3 are spaced apart from each other and are individually formed. Thus, all of the inorganic layers IL1 to IL3 may be formed of the same material, or one of the inorganic layers IL1 to IL3 may be formed of a material different from that of the other two inorganic layers, or all of the inorganic layers IL1 to IL3 may be formed of materials different from each other. All of the thicknesses of the inorganic layers IL1 to IL3 may be the same as each other, or may be different from each other.

All of the layer structures of the cap layers CP1 to CP3 may be the same as each other, or the layer structure of one of the cap layers CP1 to CP3 may be different from that of the other two cap layers, or all of the layer structures of the cap layers CP1 to CP3 may be different from each other.

In the example shown in FIG. 4, in the display element 201, the upper electrode UE1 functions as an etching stopper layer ES11 when dry etching is applied to the sealing layer SE1. In the display element 202, the upper electrode UE2 functions as an etching stopper layer ES12 when dry etching is applied to the sealing layer SE2. In the display element 203, the upper electrode UE3 functions as an etching stopper layer ES13 when dry etching is applied to the sealing layer SE3.

When dry etching is applied to each of the etching stopper layer ES11 and the sealing layer SE1 on the same condition, and the etching rate of the etching stopper layer ES11 is compared with that of the sealing layer SE1, the etching rate of the etching stopper layer ES11 (or the upper electrode UE1) is less than that of the sealing layer SE1.

For example, when dry etching is applied to a stacked layer body in which the sealing layer SE1 is stacked on the etching stopper layer ES11, the sealing layer SE1 is removed, and at the same time, the progress of the etching can be stopped in the etching stopper layer ES11.

Similarly, the etching rate of the etching stopper layer ES12 (or the upper electrode UE2) is less than that of the sealing layer SE2. The etching rate of the etching stopper layer ES13 (or the upper electrode UE3) is less than that of the sealing layer SE3.

The etching stopper layers ES11 to ES13 are formed of a material different from the materials of the rib 5 and the sealing layers SE1, SE2 and SE3. For example, the rib 5 and the sealing layers SE1, SE2 and SE3 are formed of silicon nitride. The etching stopper layers ES11 to ES13 are formed of an alloy of magnesium and silver, which is a material having a high resistance to dry etching compared to silicon nitride.

In the example shown in FIG. 4, the thickness T11 of the etching stopper layer ES11 (or the upper electrode UE1) is greater than the thickness T13 of the etching stopper layer ES13 (or the upper electrode UE3) (T11>T13). The thickness T12 of the etching stopper layer ES12 (or the upper electrode UE2) is greater than the thickness T13 of the etching stopper layer ES13 (or the upper electrode UE3) (T12>T13). For example, thickness T11 is greater than thickness T12 (T11>T12). It should be noted that thickness T12 may be approximately equal to thickness T11 (T12≈T11) or thickness T11 may be less than thickness T12 (T11<T12).

The relationships between the thicknesses of the etching stopper layers ES11 to ES13 and the colors of the display elements 201 to 203 are as follows.

The display element 203 comprising the thinnest etching stopper layer ES13 is configured to emit light in a blue wavelength range as the third wavelength range. Thus, the light emitting layer EM3 is formed of a material which emits light in a blue wavelength range.

The display element 201 comprising the etching stopper layer ES11 having thickness T11 is configured to emit light in a red wavelength range as the first wavelength range. The light emitting layer EM1 is formed of a material which emits light in a red wavelength range.

The display element 202 comprising the etching stopper layer ES12 having thickness T12 is configured to emit light in a green wavelength range as the second wavelength range. The light emitting layer EM2 is formed of a material which emits light in a green wavelength range.

Alternatively, the display element 201 may be configured to emit light in a green wavelength range as the first wavelength range, and the display element 202 may be configured to emit light in a red wavelength range as the second wavelength range. In this case, the light emitting layer EM1 is formed of a material which emits light in a green wavelength range, and the light emitting layer EM2 is formed of a material which emits light in a red wavelength range.

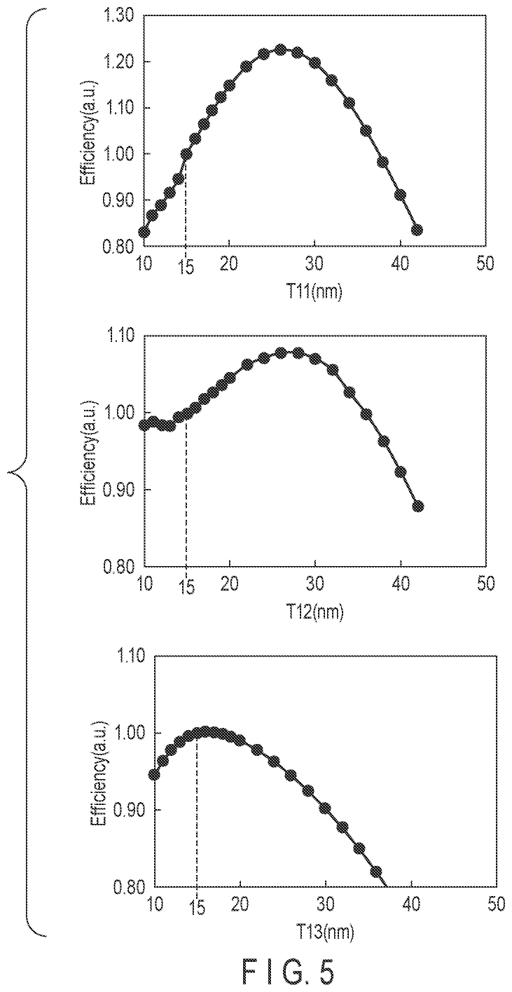

FIG. 5 is a diagram showing an example of the simulation results of the relationships between the thicknesses of the etching stopper layers shown in FIG. 4 and the luminous efficiency.

In each graph shown in FIG. 5, the horizontal axis indicates the thickness of the etching stopper layer, and the vertical axis indicates the luminous efficiency. Here, the luminous efficiency is defined as a value (cd/A) obtained by dividing the luminance (cd/m²) of light emitted from the display element by current density (A/m²). It should be noted that the luminous efficiency of the vertical axis is a value which is normalized assuming that the luminous efficiency is 1 when the thickness of the etching stopper layer is 15 nm.

The upper part of FIG. 5 shows the simulation result of the relationship between the thickness T11 of the etching stopper layer ES11 and the luminous efficiency in the display element 201.

The middle part of FIG. 5 shows the simulation result of the relationship between the thickness T12 of the etching stopper layer ES12 and the luminous efficiency in the display element 202.

The lower part of FIG. 5 shows the simulation result of the relationship between the thickness T13 of the etching stopper layer ES13 and the luminous efficiency in the display element 203.

In the chromaticity diagram of a CIE color system, for example, of light emitted from the display element 201 in a red wavelength range, the chromaticity coordinates of light in which the luminous efficiency should be considered are (x=0.69, y=0.31). For example, of light emitted from the display element 202 in a green wavelength range, the chromaticity coordinates of light in which the luminous efficiency should be considered are (x=0.25, y=0.72). For example, of light emitted from the display element 203 in a blue wavelength range, the chromaticity coordinates of light in which the luminous efficiency should be considered are (x=0.14, y=0.05).

In this simulation, the luminous efficiency is calculated based on the luminance of light of the chromaticity coordinates described above regarding each of the display elements 201 to 203.

Regarding the display element 201, the following matters were confirmed. The luminous efficiency increased with increasing thickness T11, and peaked when thickness T11 was in a range from 25 nm to 28 nm. Subsequently, the luminous efficiency decreased as thickness T11 increased to approximately 40 nm.

Regarding the display element 202, the following matters were confirmed. The luminous efficiency increased with increasing thickness T12, and peaked when thickness T12 was in a range from 25 nm to 30 nm. Subsequently, the luminous efficiency decreased as thickness T12 increased to approximately 40 nm.

Regarding the display element 203, the following matters were confirmed. The luminous efficiency increased with increasing thickness T13, and peaked when thickness T13 was in a range from 15 nm to 18 nm. Subsequently, the luminous efficiency decreased as thickness T13 increased to approximately 40 nm.

Based on these simulation results, thicknesses T11 to T13 are set such that the luminous efficiency exhibits a peak or its vicinity. Thickness T11 and thickness T12 are set to be greater than thickness T13.

The etching stopper layers ES11 to ES13 are spaced apart from each other and are individually formed. For this reason, the thickness of each of the etching stopper layers ES11 to ES13 can be freely set and can be easily optimized.

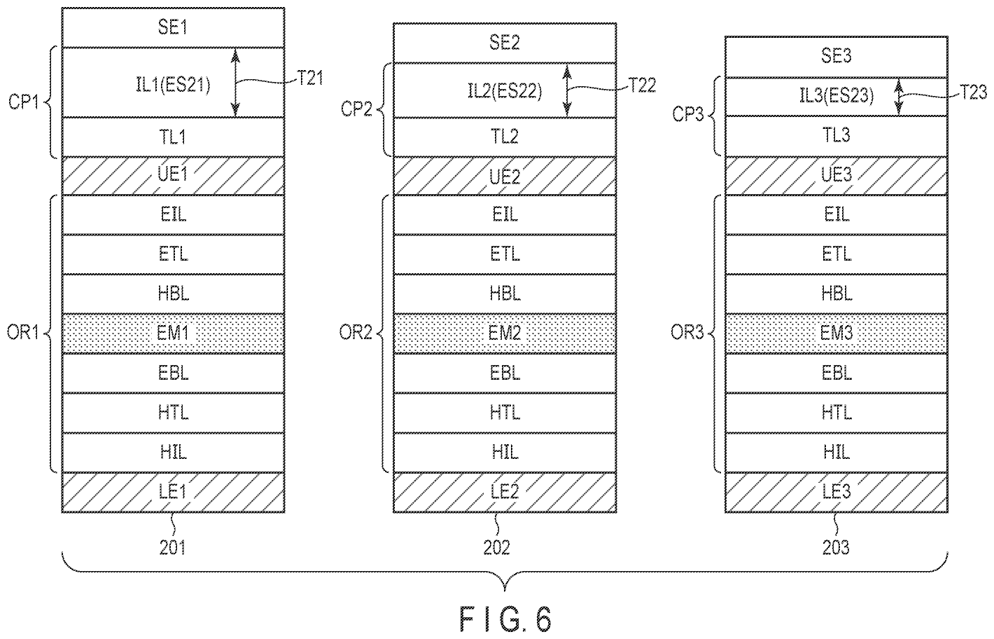

FIG. 6 is a diagram showing another example of the configuration of the display elements 201 to 203. The example shown in FIG. 6 corresponds to an example in which each inorganic layer functions as an etching stopper layer.

In other words, in the display element 201, the inorganic layer IL1 functions as an etching stopper layer ES21 when dry etching is applied to the sealing layer SE1. In the display element 202, the inorganic layer IL2 functions as an etching stopper layer ES22 when dry etching is applied to the sealing layer SE2. In the display element 203, the inorganic layer IL3 functions as an etching stopper layer ES23 when dry etching is applied to the sealing layer SE3.

When dry etching is applied to each of the etching stopper layer ES21 and the sealing layer SE1 on the same condition, and the etching rate of the etching stopper layer ES21 is compared with that of the sealing layer SE1, the etching rate of the etching stopper layer ES21 (or the inorganic layer IL1) is less than that of the sealing layer SE1.

Similarly, the etching rate of the etching stopper layer ES22 (or the inorganic layer IL2) is less than that of the sealing layer SE2. Similarly, the etching rate of the etching stopper layer ES23 (or the inorganic layer IL3) is less than that of the sealing layer SE3.

The etching stopper layers ES21 to ES23 are formed of a material different from the materials of the rib 5 and the sealing layers SE1, SE2 and SE3. For example, the rib 5 and the sealing layers SE1, SE2 and SE3 are formed of silicon nitride. The etching stopper layers ES21 to ES23 are formed of lithium fluoride or silicon oxide, which is a material having a high resistance to dry etching compared to silicon nitride.

In the example shown in FIG. 6, the thickness T21 of the etching stopper layer ES21 (or the inorganic layer IL1) is greater than the thickness T23 of the etching stopper layer ES23 (or the inorganic layer IL3) (T21>T23). The thickness T22 of the etching stopper layer ES22 (or the inorganic layer IL2) is greater than the thickness T23 of the etching stopper layer ES23 (or the inorganic layer IL3) (T22>T23). For example, thickness T21 is greater than thickness T22 (T21>T22). It should be noted that thickness T22 may be approximately equal to thickness T21 (T22≈T21) or thickness T21 may be less than thickness T22 (T21<T22).

The relationships between the thicknesses of the etching stopper layers ES21 to ES23 and the colors of the display elements 201 to 203 are as follows.

The display element 203 comprising the thinnest etching stopper layer ES23 is configured to emit light in a blue wavelength range as the third wavelength range. Thus, the light emitting layer EM3 is formed of a material which emits light in a blue wavelength range.

The display element 201 comprising the etching stopper layer ES21 having thickness T21 is configured to emit light in a red wavelength range as the first wavelength range. The light emitting layer EM1 is formed of a material which emits light in a red wavelength range.

The display element 202 comprising the etching stopper layer ES22 having thickness T22 is configured to emit light in a green wavelength range as the second wavelength range. The light emitting layer EM2 is formed of a material which emits light in a green wavelength range.

Alternatively, the display element 201 may be configured to emit light in a green wavelength range as the first wavelength range, and the display element 202 may be configured to emit light in a red wavelength range as the second wavelength range. In this case, the light emitting layer EM1 is formed of a material which emits light in a green wavelength range, and the light emitting layer EM2 is formed of a material which emits light in a red wavelength range.

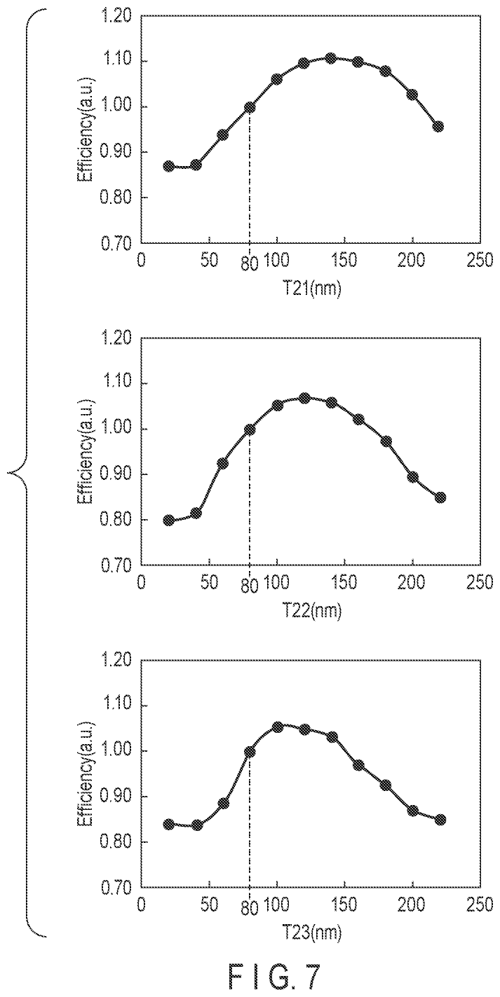

FIG. 7 is a diagram showing an example of the simulation results of the relationships between the thicknesses of the etching stopper layers shown in FIG. 6 and the luminous efficiency.

In each graph shown in FIG. 7, the horizontal axis indicates the thickness of the etching stopper layer, and the vertical axis indicates the luminous efficiency. The definition of the luminous efficiency shown here is as explained with reference to FIG. 5. It should be noted that the luminous efficiency of the vertical axis is a value which is normalized assuming that the luminous efficiency is 1 when the thickness of the etching stopper layer is 80 nm.

The upper part of FIG. 7 shows the simulation result of the relationship between the thickness T21 of the etching stopper layer ES21 and the luminous efficiency in the display element 201. In this simulation, the luminous efficiency is calculated based on the luminance of, of light emitted from the display element 201 in a red wavelength range, light in which the chromaticity coordinates are (x=0.69, y=0.31).

The middle part of FIG. 7 shows the simulation result of the relationship between the thickness T22 of the etching stopper layer ES22 and the luminous efficiency in the display element 202. In this simulation, the luminous efficiency is calculated based on the luminance of, of light emitted from the display element 202 in a green wavelength range, light in which the chromaticity coordinates are (x=0.25, y=0.72).

The lower part of FIG. 7 shows the simulation result of the relationship between the thickness T23 of the etching stopper layer ES23 and the luminous efficiency in the display element 203. In this simulation, the luminous efficiency is calculated based on the luminance of, of light emitted from the display element 203 in a blue wavelength range, light in which the chromaticity coordinates are (x=0.14, y=0.05).

Regarding the display element 201, the following matters were confirmed. The luminous efficiency increased with increasing thickness T21, and peaked when thickness T21 was approximately 140 nm. Subsequently, the luminous efficiency decreased as thickness T21 increased to approximately 250 nm.

Regarding the display element 202, the following matters were confirmed. The luminous efficiency increased with increasing thickness T22, and peaked when thickness T22 was approximately 120 nm. Subsequently, the luminous efficiency decreased as thickness T22 increased to approximately 250 nm.

Regarding the display element 203, the following matters were confirmed. The luminous efficiency increased with increasing thickness T23, and peaked when thickness T23 was approximately 100 nm. Subsequently, the luminous efficiency decreased as thickness T23 increased to approximately 250 nm.

Based on these simulation results, thicknesses T21 to T23 are set such that the luminous efficiency exhibits a peak or its vicinity. Thickness T21 and thickness T22 are set to be greater than thickness T23. Thickness T21 is set to be greater than thickness T22.

The etching stopper layers ES21 to ES23 are spaced apart from each other and are individually formed. For this reason, the thickness of each of the etching stopper layers ES21 to ES23 can be freely set and can be easily optimized.

In the example explained with reference to FIG. 4 and FIG. 5, the upper electrodes UE1 to UE3 function as etching stopper layers. In the example explained with reference to FIG. 6 and FIG. 7, the inorganic layers IL1 to IL3 of the cap layers function as etching stopper layers. It should be noted that these examples may be combined with each other.

In other words, in the display element 201, at least one of the upper electrode UE1 and the inorganic layer IL1 may be configured to function as an etching stopper layer. In the display element 202, at least one of the upper electrode UE2 and the inorganic layer IL2 may be configured to function as an etching stopper layer. In the display element 203, at least one of the upper electrode UE3 and the inorganic layer IL3 may be configured to function as an etching stopper layer.

Now, this specification explains an example of the manufacturing method of the display device DSP.

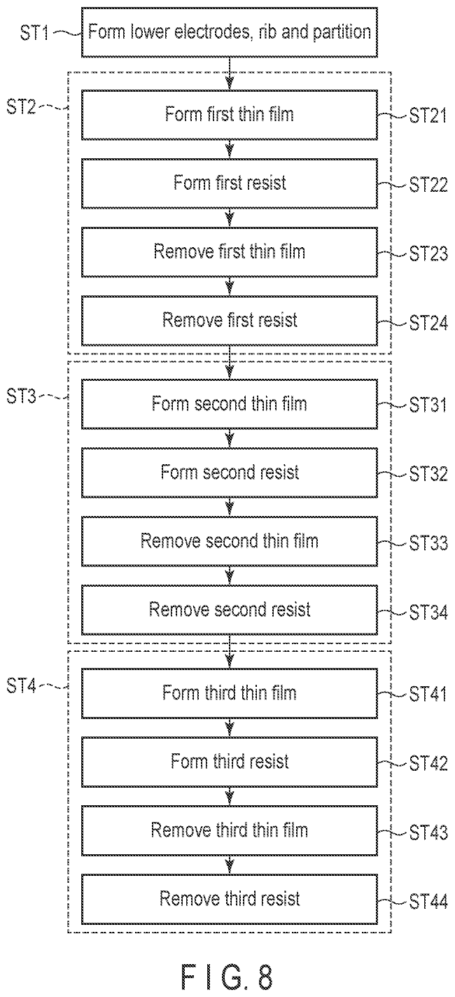

FIG. 8 is a flow diagram for explaining an example of the manufacturing method of the display device DSP.

The manufacturing method shown here roughly includes the process of preparing a processing substrate SUB comprising subpixels SP1, SP2 and SP3 (step ST1), the process of forming the display element 201 of the subpixel SP1 (step ST2), the process of forming the display element 202 of the subpixel SP2 (step ST3) and the process of forming the display element 203 of the subpixel SP3 (step ST4).

Regarding the order of the processes of forming the display elements 201, 202 and 203, a display element having a thicker etching stopper layer should be preferably formed in an earlier process. In other words, a display element having a thinner etching stopper layer should be preferably formed in a later process.

As explained with reference to FIG. 4 to FIG. 7, the etching stopper layer (ES13 or ES23) of the display element 203 is thinner than the etching stopper layer (ES11 or ES21) of the display element 201 and is thinner than the etching stopper layer (ES12 or ES22) of the display element 202. Thus, the display elements 201 and 202 are formed before the formation of the display element 203. When the etching stopper layer (ES12 or ES22) of the display element 202 is thinner than the etching stopper layer (ES11 or ES21) of the display element 201, the display element 201 is formed before the formation of the display element 202. Thus, the display elements 201 to 203 are formed in the order shown in FIG. 8.

In step ST1, first, the processing substrate SUB is prepared by forming the lower electrode LE1 of the subpixel SP1, the lower electrode LE2 of the subpixel SP2, the lower electrode LE3 of the subpixel SP3, the rib 5 and the partition 6 on the substrate 10. The details are described later.

In step ST2, first, a first thin film 31 including the light emitting layer EM1 is formed on the processing substrate SUB (step ST21). Subsequently, a first resist 41 patterned into a predetermined shape is formed on the first thin film 31 (step ST22). Subsequently, part of the first thin film 31 is removed by etching using the first resist 41 as a mask (step ST23). Subsequently, the first resist 41 is removed (step ST24). In this way, the subpixel SP1 is formed. The subpixel SP1 comprises the display element 201 comprising the first thin film 31 having a predetermined shape.

In step ST3, first, a second thin film 32 including the light emitting layer EM2 is formed on the processing substrate SUB (step ST31). Subsequently, a second resist 42 patterned into a predetermined shape is formed on the second thin film 32 (step ST32). Subsequently, part of the second thin film 32 is removed by etching using the second resist 42 as a mask (step ST33). Subsequently, the second resist 42 is removed (step ST34). In this way, the subpixel SP2 is formed. The subpixel SP2 comprises the display element 202 comprising the second thin film 32 having a predetermined shape.

In step ST4, first, a third thin film 33 including the light emitting layer EM3 is formed on the processing substrate SUB (step ST41). Subsequently, a third resist 43 patterned into a predetermined shape is formed on the third thin film 33 (step ST42). Subsequently, part of the third thin film 33 is removed by etching using the third resist 43 as a mask (step ST43). Subsequently, the third resist 43 is removed (step ST44). In this way, the subpixel SP3 is formed. The subpixel SP3 comprises the display element 203 comprising the third thin film 33 having a predetermined shape.

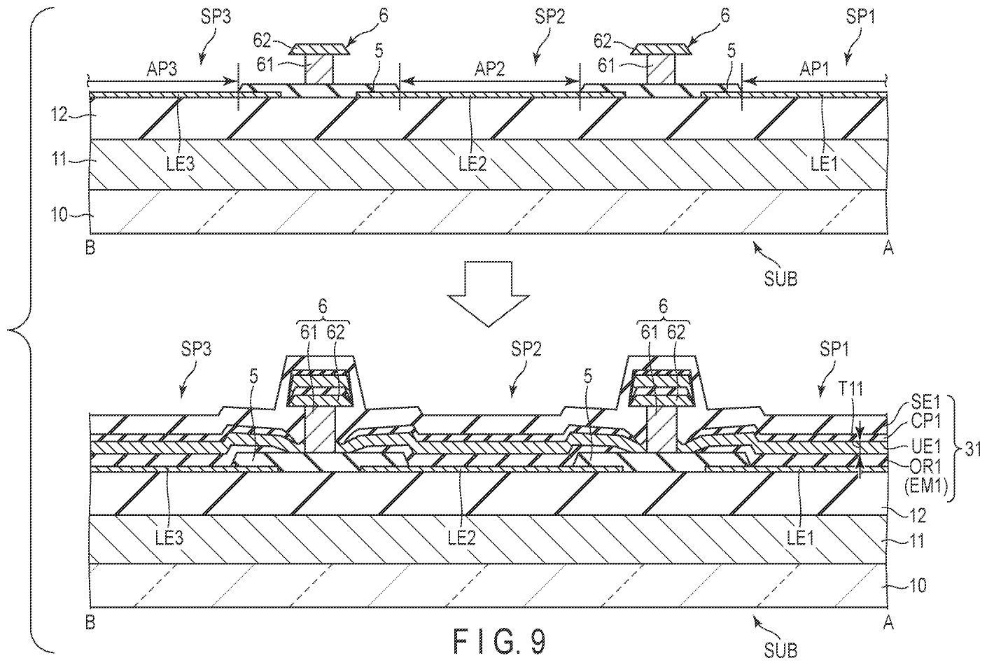

Now, this specification explains an example in which each upper electrode functions as an etching stopper layer with reference to FIG. 9 to FIG. 18 regarding steps ST1 to ST4.

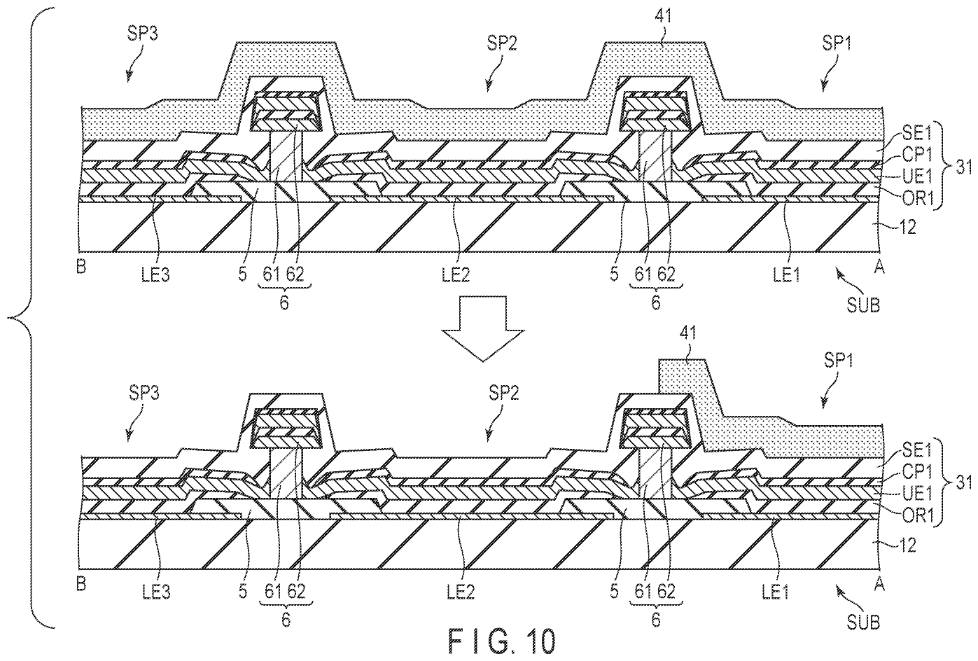

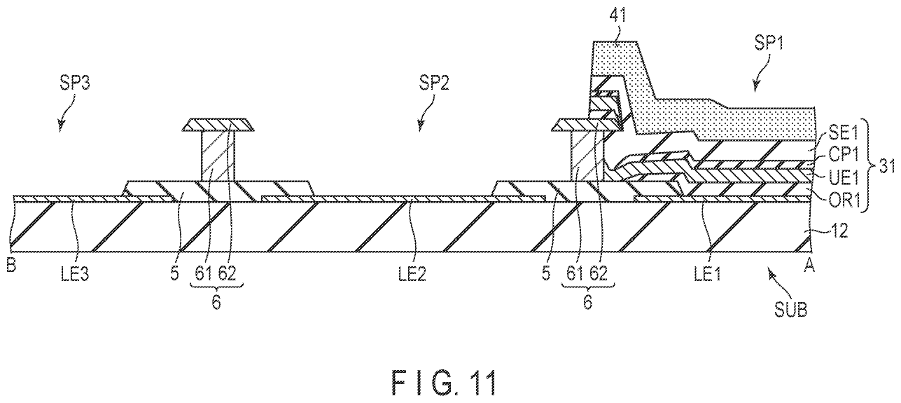

First, in step ST1, as shown in the upper part of FIG. 9, the processing substrate SUB is prepared. The process of preparing the processing substrate SUB includes the process of forming the circuit layer 11 on the substrate 10, the process of forming the insulating layer 12 on the circuit layer 11, the process of forming the lower electrode LE1 of the subpixel SP1, the lower electrode LE2 of the subpixel SP2 and the lower electrode LE3 of the subpixel SP3 on the insulating layer 12, the process of forming the rib 5 comprising the apertures AP1, AP2 and AP3 overlapping the lower electrodes LE1, LE2 and LE3, respectively, and the process of forming the partition 6 including the lower portion 61 provided on the rib 5 and the upper portion 62 provided on the lower portion 61 and protruding from the side surfaces of the lower portion 61. The section shown in each of FIG. 9 to FIG. 11 and FIG. 13 to FIG. 18 corresponds to, for example, the section taken along the A-B line of FIG. 2. In FIG. 10, FIG. 11 and FIG. 13 to FIG. 18, the illustrations of the substrate 10 and the circuit layer 11 lower than the insulating layer 12 are omitted.

Subsequently, in step ST21, as shown in the lower part of FIG. 9, the first thin film 31 is formed over the subpixel SP1, the subpixel SP2 and the subpixel SP3. The process of forming the first thin film 31 includes, on the processing substrate SUB, the process of forming the organic layer OR1 including the light emitting layer EM1 which emits light in a red wavelength range, the process of forming the upper electrode UE1 as an etching stopper layer on the organic layer OR1, the process of forming the cap layer CP1 on the upper electrode UE1 and the process of forming the sealing layer SE1 on the cap layer CP1.

The organic layer OR1 is formed on each of the lower electrode LE1, the lower electrode LE2 and the lower electrode LE3 and is also formed on each partition 6. Of the organic layer OR1, the portion formed on each upper portion 62 is spaced apart from the portion formed on each of the lower electrodes.

The upper electrode UE1 is formed on the organic layer OR1 immediately above each of the lower electrode LE1, the lower electrode LE2 and the lower electrode LE3, covers the rib 5 and is in contact with the lower portion 61 of each partition 6. The upper electrode UE1 is also formed on the organic layer OR1 immediately above each upper portion 62. Of the upper electrode UE1, the portion which is formed immediately above each upper portion 62 is spaced apart from the portion which is formed immediately above each of the lower electrodes. The upper electrode UE1 has thickness T11.

The cap layer CP1 includes the transparent layer TL1 and the inorganic layer IL1 (not shown). The cap layer CP1 is formed on the upper electrode UE1 immediately above each of the lower electrode LE1, the lower electrode LE2 and the lower electrode LE3, and is also formed on the upper electrode UE1 immediately above each upper portion 62. Of the cap layer CP1, the portion which is formed immediately above each upper portion 62 is spaced apart from the portion which is formed immediately above each of the lower electrodes.

The sealing layer SE1 is formed so as to cover the cap layer CP1 and the partitions 6. In other words, the sealing layer SE1 is formed on the cap layer CP1 immediately above each of the lower electrode LE1, the lower electrode LE2 and the lower electrode LE3, and is also formed on the cap layer CP1 immediately above each upper portion 62. In the sealing layer SE1, the portion which is formed immediately above each upper portion 62 is continuous with the portion which is formed immediately above each of the lower electrodes.

Subsequently, in step ST22, as shown in the upper part of FIG. 10, the first resist 41 is applied over the entire surface of the sealing layer SE1. Subsequently, as shown in the lower part of FIG. 10, the first resist 41 is patterned. The first resist 41 covers the first thin film 31 of the subpixel SP1, and the first thin film 31 is exposed from the first resist 41 in subpixels SP2 and SP3. Thus, the first resist 41 is provided immediately above the lower electrode LE1. The first resist 41 extends from the subpixel SP1 to the upper side of the partition 6. On the partition 6 between the subpixel SP1 and the subpixel SP2, the first resist 41 is provided on the subpixel SP1 side (the right side of the figure), and the sealing layer SE1 is exposed from the first resist 41 on the subpixel SP2 side (the left side of the figure). The sealing layer SE1 is exposed from the first resist 41 in the subpixel SP2 and the subpixel SP3.

Subsequently, in step ST23, as shown in FIG. 11, etching is applied using the first resist 41 as a mask. By this process, the first thin film 31 exposed from the first resist 41 in subpixels SP2 and SP3 is removed, and the first thin film 31 remains in the subpixel SP1. In this way, the lower electrode LE2 is exposed in the subpixel SP2, and the rib 5 surrounding the lower electrode LE2 is exposed. In the subpixel SP3, the lower electrode LE3 is exposed, and the rib 5 surrounding the lower electrode LE3 is exposed. On the partition 6 between the subpixel SP1 and the subpixel SP2, the subpixel SP2 side is exposed. Further, the partition 6 between the subpixel SP2 and the subpixel SP3 is exposed.

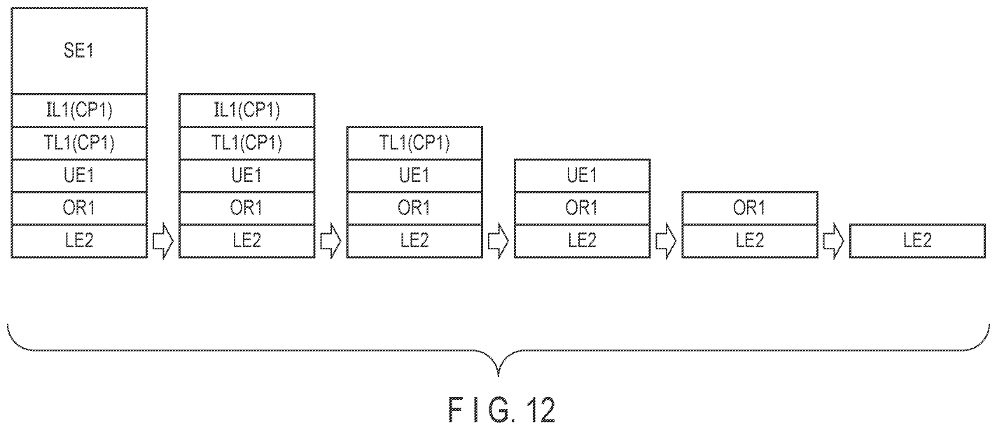

FIG. 12 is a diagram for explaining the process of removing the first thin film 31 in the subpixel SP2. The sections of the first thin film 31 on the lower electrode LE2 are arranged in the removal order from the left to right of the figure.

First, dry etching is performed using the first resist 41 as a mask to remove the sealing layer SE1 exposed from the first resist 41.

Subsequently, wet etching is performed using the first resist 41 as a mask to remove the inorganic layer IL1 of the cap layer CP1 exposed from the sealing layer SE1.

Subsequently, dry etching is performed using the first resist 41 as a mask to remove the transparent layer TL1 of the cap layer CP1 exposed from the inorganic layer IL1.

Subsequently, wet etching is performed using the first resist 41 as a mask to remove the upper electrode UE1 exposed from the transparent layer TL1.

Subsequently, dry etching is performed using the first resist 41 as a mask to remove the organic layer OR1 exposed from the upper electrode UE1 such that the lower electrode LE2 is exposed.

Similarly, in the subpixel SP3, the sealing layer SE1, the cap layer CP1, the upper electrode UE1 and the organic layer OR1 are removed.

As shown in the lower part of FIG. 10, before etching is applied to the sealing layer SE1, in subpixels SP2 and SP3, the upper electrode UE1 between the rib 5 and the sealing layer SE1 covers the rib 5 between the partition 6 and the organic layer OR1. Thus, the sealing layer SE1 is not in contact with the rib 5. The upper electrode UE1 functions as an etching stopper layer. The etching rate of the upper electrode UE1 is less than that of the sealing layer SE1. Thus, regarding the dry etching of the sealing layer SE1, after the sealing layer SE1 is completely removed, the progress of dry etching can be stopped in the upper electrode UE1. By this configuration, the rib 5 is not substantially damaged when dry etching is applied to the sealing layer SE1. This configuration prevents the formation of an undesired hole (a penetration path for moisture) which penetrates the rib 5 so as to expose the insulating layer 12. Further, the configuration prevents the change in the colors of the lower electrodes because of the effect of undesired moisture. Moreover, the configuration prevents an occurrence of pixel defects in which the organic EL elements do not emit light because of damage to the anodes and the organic EL elements.

In this way, the reduction in reliability can be prevented.

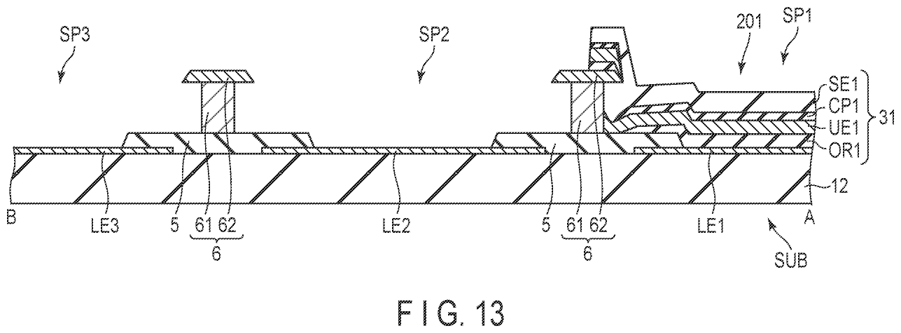

Subsequently, in step ST24, as shown in FIG. 13, the first resist 41 is removed. Thus, the sealing layer SE1 of the subpixel SP1 is exposed. Through these steps ST21 to ST24, the display element 201 is formed in the subpixel SP1. The display element 201 consists of the lower electrode LE1, the organic layer OR1 including the light emitting layer EM1, the upper electrode UE1 and the cap layer CP1. The display element 201 is covered with the sealing layer SE1.

A stacked layer body of the organic layer OR1 including the light emitting layer EM1, the upper electrode UE1, the cap layer CP1 and the sealing layer SE1 is formed on the partition 6 between the subpixel SP1 and the subpixel SP2. Of the partition 6, the portion on the subpixel SP1 side is covered with the sealing layer SE1.

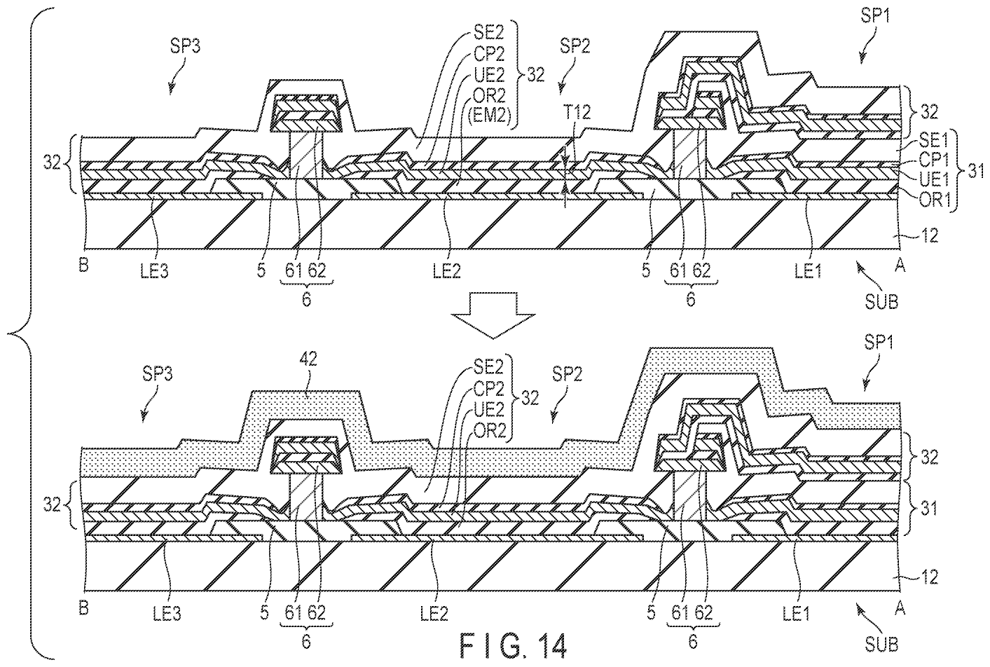

Subsequently, in step ST31, as shown in the upper part of FIG. 14, the second thin film 32 is formed over the subpixel SP1, the subpixel SP2 and the subpixel SP3. The second thin film 32 covers the first thin film 31 in the subpixel SP1. The process of forming the second thin film 32 includes, on the processing substrate SUB, the process of forming the organic layer OR2 including the light emitting layer EM2 which emits light in a green wavelength range, the process of forming the upper electrode UE2 on the organic layer OR2, the process of forming the cap layer CP2 on the upper electrode UE2 and the process of forming the sealing layer SE2 on the cap layer CP2.

The organic layer OR2 is formed on each of the lower electrode LE2 and the lower electrode LE3 and is also formed on the sealing layer SE1 of the subpixel SP1. The organic layer OR2 is also formed on each partition 6. Of the organic layer OR2, the portion formed on each partition 6 is spaced apart from the portion which is formed immediately above the lower electrode LE2 and the portion which is formed immediately above the lower electrode LE3.

The upper electrode UE2 is formed on the organic layer OR2. The upper electrode UE2 which is formed immediately above each of the lower electrode LE2 and the lower electrode LE3 covers the rib 5 and is in contact with the lower portion 61 of the partition 6. The upper electrode UE2 is also formed on the organic layer OR2 immediately above the partition 6. The upper electrode UE2 has thickness T12. Thickness T12 is equal to thickness T11 or less than thickness T11.

The cap layer CP2 is formed on the upper electrode UE2 immediately above each of the lower electrode LE1, the lower electrode LE2 and the lower electrode LE3, and is also formed on the upper electrode UE2 immediately above each partition 6.

The sealing layer SE2 is formed so as to cover the cap layer CP2 and the partitions 6. In other words, the sealing layer SE2 is formed on the cap layer CP2 immediately above each of the lower electrode LE1, the lower electrode LE2 and the lower electrode LE3, and is also formed on the cap layer CP2 immediately above each partition 6.

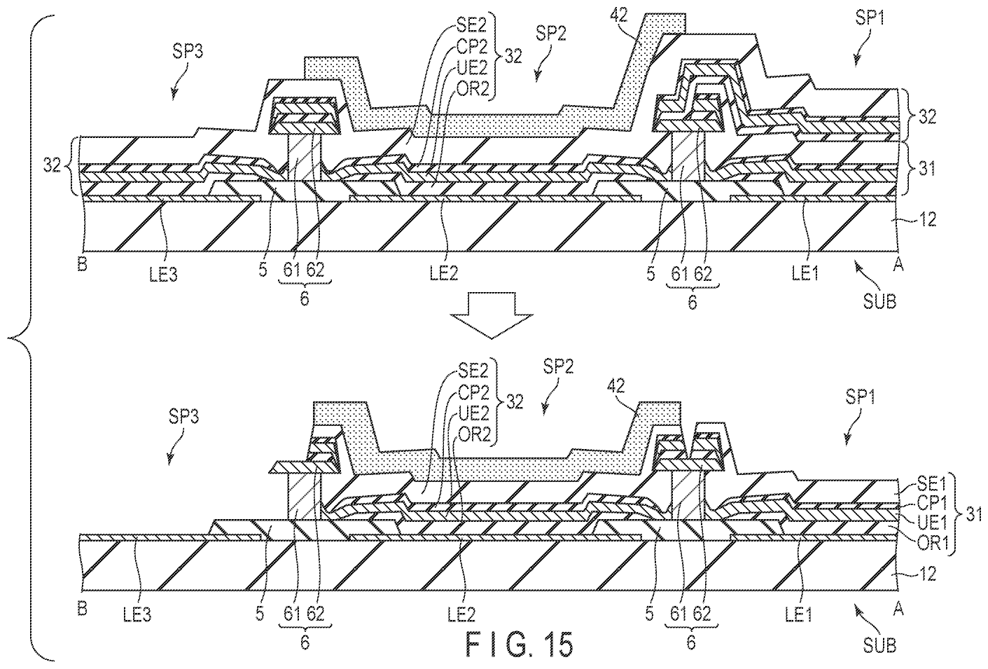

Subsequently, in step ST32, as shown in the lower part of FIG. 14, the second resist 42 is applied over the entire surface of the sealing layer SE2. Subsequently, as shown in the upper part of FIG. 15, the second resist 42 is patterned. The second resist 42 covers the second thin film 32 of the subpixel SP2, and the second thin film 32 is exposed from the second resist 42 in subpixels SP1 and SP3. Thus, the second resist 42 is provided immediately above the lower electrode LE2. The second resist 42 extends from the subpixel SP2 to the upper side of each partition 6. The sealing layer SE2 is exposed from the second resist 42 in the subpixel SP1 and the subpixel SP3.

Subsequently, in step ST33, as shown in the lower part of FIG. 15, etching is applied using the second resist 42 as a mask. By this process, the second thin film 32 exposed from the second resist 42 in subpixels SP1 and SP3 is removed, and the second thin film 32 remains in the subpixel SP2. In this way, the sealing layer SE1 of the subpixel SP1 is exposed, and the lower electrode LE3 is exposed in the subpixel SP3. Further, the rib 5 surrounding the lower electrode LE3 is also exposed.

On the partition 6 between the subpixel SP1 and the subpixel SP2, the first thin film 31 is divided from the second thin film 32. In other words, the sealing layer SE2, the cap layer CP2, the upper electrode UE2 and the organic layer OR2 remaining on the partition 6 are spaced apart from the sealing layer SE1, the cap layer CP1, the upper electrode UE1 and the organic layer OR1 remaining on the partition 6. On the partition 6 between the subpixel SP2 and the subpixel SP3, the subpixel SP3 side of the partition 6 is exposed.

As shown in the upper part of FIG. 15, before etching is applied to the sealing layer SE2, in the subpixel SP3, the upper electrode UE2 between the rib 5 and the sealing layer SE2 covers the rib 5 between the partition 6 and the organic layer OR2. Thus, the sealing layer SE2 is not in contact with the rib 5. The upper electrode UE2 functions as an etching stopper layer. The etching rate of the upper electrode UE2 is less than that of the sealing layer SE2. Thus, regarding the dry etching of the sealing layer SE2, after the sealing layer SE2 is completely removed, the progress of dry etching can be stopped in the upper electrode UE2. By this configuration, the rib 5 is not substantially damaged when dry etching is applied to the sealing layer SE2. In this way, the reduction in reliability can be prevented.

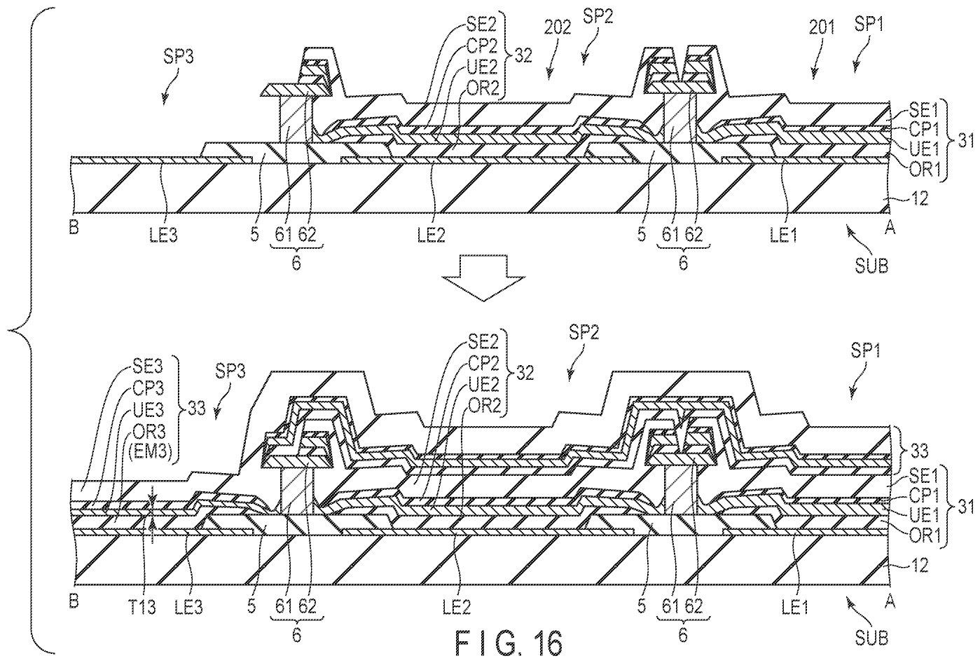

Subsequently, in step ST34, as shown in the upper part of FIG. 16, the second resist 42 is removed. Thus, the sealing layer SE2 of the subpixel SP2 is exposed. Through these steps ST31 to ST34, the display element 202 is formed in the subpixel SP2. The display element 202 consists of the lower electrode LE2, the organic layer OR2 including the light emitting layer EM2, the upper electrode UE2 and the cap layer CP2. The display element 202 is covered with the sealing layer SE2.

A stacked layer body of the organic layer OR2 including the light emitting layer EM2, the upper electrode UE2, the cap layer CP2 and the sealing layer SE2 is formed on the partition 6 between the subpixel SP1 and the subpixel SP2 and on the partition 6 between the subpixel SP2 and the subpixel SP3. Of each partition 6, the portion on the subpixel SP2 side is covered with the sealing layer SE2.

Subsequently, in step ST41, as shown in the lower part of FIG. 16, the third thin film 33 is formed over the subpixel SP1, the subpixel SP2 and the subpixel SP3. The third thin film 33 covers the first thin film 31 in the subpixel SP1 and covers the second thin film 32 in the subpixel SP2. The process of forming the third thin film 33 includes, on the processing substrate SUB, the process of forming the organic layer OR3 including the light emitting layer EM3 which emits light in a blue wavelength range, the process of forming the upper electrode UE3 on the organic layer OR3, the process of forming the cap layer CP3 on the upper electrode UE3 and the process of forming the sealing layer SE3 on the cap layer CP3.

The organic layer OR3 is formed on the lower electrode LE3, and is also formed on the sealing layer SE1 of the subpixel SP1, and further, is formed on the sealing layer SE2 of the subpixel SP2. The organic layer OR3 is also formed on each partition 6. On the partition 6 between the subpixel SP1 and the subpixel SP2, the organic layer OR3 covers the first thin film 31 and the second thin film 32. Of the organic layer OR3, the portion formed on the partition 6 between the subpixel SP2 and the subpixel SP3 is spaced apart from the portion which is formed immediately above the lower electrode LE3.

The upper electrode UE3 is formed on the organic layer OR3. The upper electrode UE3 which is formed immediately above the lower electrode LE3 covers the rib 5 and is in contact with the lower portion 61 of the partition 6. The upper electrode UE3 is also formed on the organic layer OR3 immediately above the partition 6. The upper electrode UE3 has thickness T13. Thickness T13 is less than thicknesses T11 and T12.

The cap layer CP3 is formed on the upper electrode UE3 immediately above each of the lower electrode LE1, the lower electrode LE2 and the lower electrode LE3, and is also formed on the upper electrode UE3 immediately above each partition 6.

The sealing layer SE3 is formed so as to cover the cap layer CP3 and the partitions 6. In other words, the sealing layer SE3 is formed on the cap layer CP3 immediately above each of the lower electrode LE1, the lower electrode LE2 and the lower electrode LE3, and is also formed on the cap layer CP3 immediately above each upper portion 62.

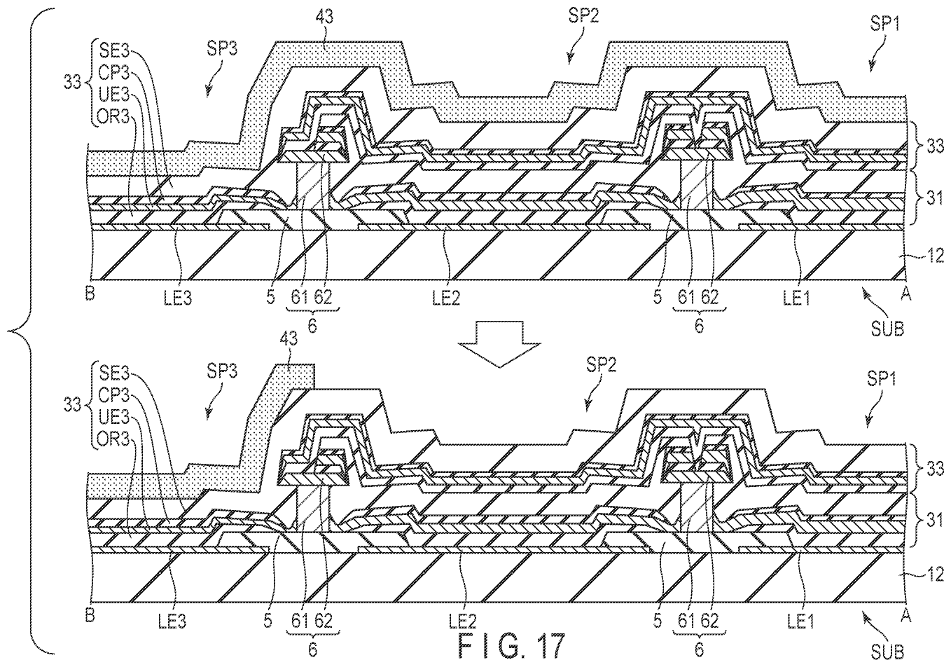

Subsequently, in step ST42, as shown in the upper part of FIG. 17, the third resist 43 is applied over the entire surface of the sealing layer SE3. Subsequently, as shown in the lower part of FIG. 17, the third resist 43 is patterned. The third resist 43 covers the third thin film 33 of the subpixel SP3, and the third thin film 33 is exposed from the third resist 43 in subpixels SP1 and SP2. Thus, the third resist 43 is provided immediately above the lower electrode LE3. The third resist 43 extends from the subpixel SP3 to the upper side of the partition 6. The sealing layer SE3 is exposed from the third resist 43 in the subpixel SP1 and the subpixel SP2.

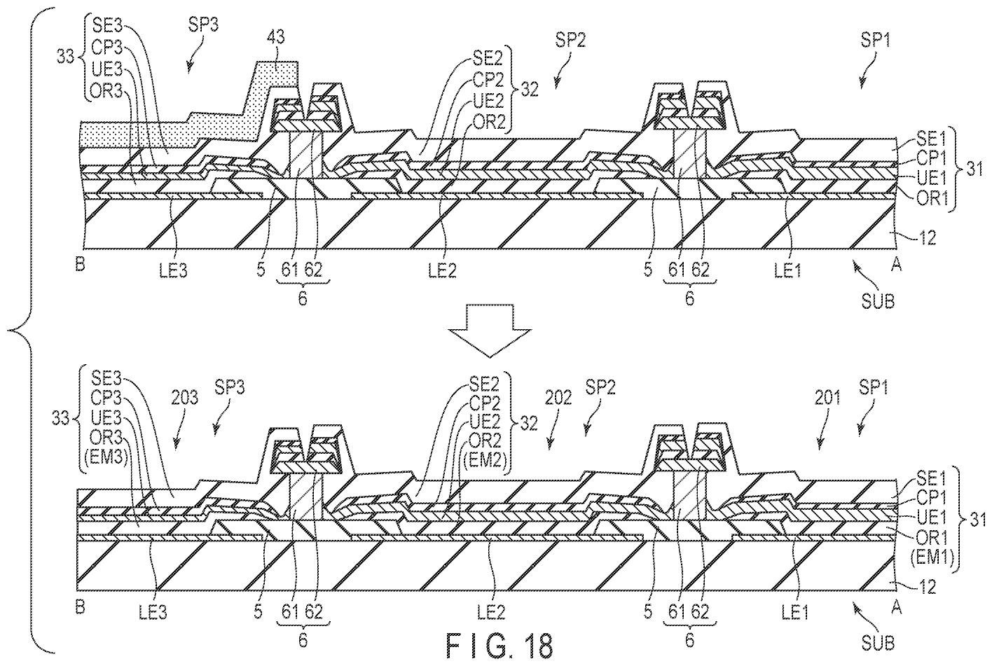

Subsequently, in step ST43, as shown in the upper part of FIG. 18, etching is applied using the third resist 43 as a mask. By this process, the third thin film 33 exposed from the third resist 43 in subpixels SP1 and SP2 is removed, and the third thin film 33 remains in the subpixel SP3. In this way, the sealing layer SE1 of the subpixel SP1 is exposed, and the sealing layer SE2 of the subpixel SP2 is exposed.

On the partition 6 between the subpixel SP1 and the subpixel SP2, the third thin film 33 is removed such that the first thin film 31 and the second thin film 32 are partly exposed.

On the partition 6 between the subpixel SP2 and the subpixel SP3, the second thin film 32 is divided from the third thin film 33. In other words, the sealing layer SE3, the cap layer CP3, the upper electrode UE3 and the organic layer OR3 remaining on the partition 6 are spaced apart from the sealing layer SE2, the cap layer CP2, the upper electrode UE2 and the organic layer OR2 remaining on the partition 6.

Subsequently, in step ST44, as shown in the lower part of FIG. 18, the third resist 43 is removed. Thus, the sealing layer SE3 of the subpixel SP3 is exposed. Through these steps ST41 to ST44, the display element 203 is formed in the subpixel SP3. The display element 203 consists of the lower electrode LE3, the organic layer OR3 including the light emitting layer EM3, the upper electrode UE3 and the cap layer CP3. The display element 203 is covered with the sealing layer SE3.

A stacked layer body of the organic layer OR3 including the light emitting layer EM3, the upper electrode UE3, the cap layer CP3 and the sealing layer SE3 is formed on the partition 6 between the subpixel SP2 and the subpixel SP3.

By the above processes, the display element 201 is formed in the subpixel SP1. The display element 202 is formed in the subpixel SP2. The display element 203 is formed in the subpixel SP3.

Of the processes described above, in the process of forming the first thin film 31 in step ST21, the light emitting layer EM1 may be formed of a material which emits light in a green wavelength range. In the process of forming the second thin film 32 in step ST31, the light emitting layer EM2 may be formed of a material which emits light in a red wavelength range.

In the above example, the subpixel SP1 corresponds to a first subpixel. The aperture AP1 corresponds to a first aperture. The lower electrode LE1 corresponds to a first lower electrode. The organic layer OR1 corresponds to a first organic layer. The light emitting layer EM1 corresponds to a first light emitting layer. The upper electrode UE1 corresponds to a first upper electrode. The cap layer CP1 corresponds to a first cap layer. The transparent layer TL1 corresponds to a first transparent layer. The inorganic layer IL1 corresponds to a first inorganic layer. The sealing layer SE1 corresponds to a first sealing layer. At least one of the upper electrode UE1 and the inorganic layer IL1 functions a first etching stopper layer.

Further, the subpixel SP2 corresponds to a second subpixel. The aperture AP2 corresponds to a second aperture. The lower electrode LE2 corresponds to a second lower electrode. The organic layer OR2 corresponds to a second organic layer. The light emitting layer EM2 corresponds to a second light emitting layer. The upper electrode UE2 corresponds to a second upper electrode. The cap layer CP2 corresponds to a second cap layer. The sealing layer SE2 corresponds to a second sealing layer. At least one of the upper electrode UE2 and the inorganic layer IL2 functions as a second etching stopper layer.

Further, the subpixel SP3 corresponds to a third subpixel. The aperture AP3 corresponds to a third aperture. The lower electrode LE3 corresponds to a third lower electrode. The organic layer OR3 corresponds to a third organic layer. The light emitting layer EM3 corresponds to a third light emitting layer. The upper electrode UE3 corresponds to a third upper electrode. The cap layer CP3 corresponds to a third cap layer. The sealing layer SE3 corresponds to a third sealing layer. At least one of the upper electrode UE3 and the inorganic layer IL3 functions as a third etching stopper layer.

As explained above, the present embodiment can provide a display device which can prevent the reduction in reliability and have an improved manufacturing yield and a manufacturing method thereof.

All of the display devices and manufacturing methods thereof that can be implemented by a person of ordinary skill in the art through arbitrary design changes to the display device and manufacturing method thereof described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiment by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiment and are self-explanatory from the descriptions of the specification or can be arbitrarily conceived by a person of ordinary skill in the art are considered as the effects of the present invention as a matter of course.

What is claimed is:

1. A manufacturing method of a display device, comprising:
preparing a processing substrate by forming a first lower electrode of a first subpixel, a second lower electrode of a second subpixel and a third lower electrode of a third subpixel and by forming a rib comprising a first aperture overlapping the first lower electrode, a second aperture overlapping the second lower electrode and a third aperture overlapping the third lower electrode;
forming a first thin film including a first organic layer including a first light emitting layer over the first subpixel, the second subpixel and the third subpixel, a first etching stopper layer on the rib and the first organic layer, and a first sealing layer on the first etching stopper layer;
removing the first thin film in the second subpixel and the third subpixel such that the first thin film remains in the first subpixel;
forming a second thin film including a second organic layer including a second light emitting layer over the first subpixel comprising the first thin film, the second subpixel and the third subpixel, a second etching stopper layer on the rib and the second organic layer, and a second sealing layer on the second etching stopper layer;
removing the second thin film in the first subpixel and the third subpixel such that the second thin film remains in the second subpixel;
forming a third thin film including a third organic layer including a third light emitting layer over the first subpixel comprising the first thin film, the second subpixel comprising the second thin film and the third subpixel, a third etching stopper layer on the rib and the third organic layer, and a third sealing layer on the third etching stopper layer; and
removing the third thin film in the first subpixel and the second subpixel such that the third thin film remains in the third subpixel, wherein
an etching rate of the first etching stopper layer is less than an etching rate of the first sealing layer,
an etching rate of the second etching stopper layer is less than an etching rate of the second sealing layer,
an etching rate of the third etching stopper layer is less than an etching rate of the third sealing layer, and
a thickness of each of the first etching stopper layer and the second etching stopper layer is greater than a thickness of the third etching stopper layer.

2. The manufacturing method of claim 1, wherein
the thickness of the first etching stopper layer is greater than the thickness of the second etching stopper layer.

3. The manufacturing method of claim 1, wherein
the third light emitting layer is formed of a material which emits light in a blue wavelength range.

4. The manufacturing method of claim 1, wherein
the first light emitting layer is formed of a material which emits light in a red wavelength range,
the second light emitting layer is formed of a material which emits light in a green wavelength range, and
the third light emitting layer is formed of a material which emits light in a blue wavelength range.

5. The manufacturing method of claim 1, wherein
the first light emitting layer is formed of a material which emits light in a green wavelength range,
the second light emitting layer is formed of a material which emits light in a red wavelength range, and
the third light emitting layer is formed of a material which emits light in a blue wavelength range.

6. The manufacturing method of claim 1, wherein
the preparing the processing substrate further includes forming a partition including a lower portion located on the rib and an upper portion located on the lower portion and protruding from a side surface of the lower portion.

7. The manufacturing method of claim 6, wherein
the lower portion of the partition is formed of a conductive material.

8. The manufacturing method of claim 7, wherein
the forming the first thin film includes forming a first upper electrode which is in contact with the lower portion of the partition, as the first etching stopper layer on the first organic layer.

9. The manufacturing method of claim 8, wherein
the first upper electrode is formed of an alloy of magnesium and silver.

10. The manufacturing method of claim 7, wherein
the forming the first thin film includes:
forming a first upper electrode which is located on the first organic layer and is in contact with the lower portion of the partition;
forming a first transparent layer on the first upper electrode; and
forming a first inorganic layer as the first etching stopper layer on the first transparent layer.

11. The manufacturing method of claim 10, wherein
the first inorganic layer is formed of lithium fluoride or silicon oxide.

12. The manufacturing method of claim 1, wherein
the rib, the first sealing layer, the second sealing layer and the third sealing layer are formed of silicon nitride.

13. A display device comprising:
a substrate;
a first lower electrode, a second lower electrode and a third lower electrode provided above the substrate;
a rib comprising a first aperture overlapping the first lower electrode, a second aperture overlapping the second lower electrode and a third aperture overlapping the third lower electrode;
a partition comprising a lower portion provided on the rib and an upper portion provided on the lower portion and protruding from a side surface of the lower portion;
a first organic layer provided on the first lower electrode in the first aperture and including a first light emitting layer;
a first etching stopper layer which is provided on the rib and the first organic layer and is in contact with the partition;
a first sealing layer which is provided on the first etching stopper layer and is in contact with the partition;
a second organic layer provided on the second lower electrode in the second aperture and including a second light emitting layer;
a second etching stopper layer which is provided on the rib and the second organic layer and is in contact with the partition;
a second sealing layer which is provided on the second etching stopper layer and is in contact with the partition;
a third organic layer provided on the third lower electrode in the third aperture and including a third light emitting layer;
a third etching stopper layer which is provided on the rib and the third organic layer and is in contact with the partition; and
a third sealing layer which is provided on the third etching stopper layer and is in contact with the partition, wherein
a thickness of each of the first etching stopper layer and the second etching stopper layer is greater than a thickness of the third etching stopper layer.

14. The display device of claim 13, wherein
the thickness of the first etching stopper layer is greater than the thickness of the second etching stopper layer.

15. The display device of claim 13, wherein
the third light emitting layer is formed of a material which emits light in a blue wavelength range.

16. The display device of claim 13, wherein
the first light emitting layer is formed of a material which emits light in a red wavelength range,
the second light emitting layer is formed of a material which emits light in a green wavelength range, and
the third light emitting layer is formed of a material which emits light in a blue wavelength range.

17. The display device of claim 13, wherein
the first light emitting layer is formed of a material which emits light in a green wavelength range,
the second light emitting layer is formed of a material which emits light in a red wavelength range, and
the third light emitting layer is formed of a material which emits light in a blue wavelength range.

18. The display device of claim 13, further comprising:
a first upper electrode provided on the first organic layer;
a first transparent layer provided on the first upper electrode; and
a first inorganic layer provided on the first transparent layer, wherein
at least one of the first upper electrode and the first inorganic layer is the first etching stopper layer.

19. The display device of claim 18, wherein
the first upper electrode is formed of an alloy of magnesium and silver.

20. The display device of claim 18, wherein
the first inorganic layer is formed of lithium fluoride or silicon oxide.
